(19) United States
(12) Patent Application Publication
(10) Pub. No.: US 2025/0386450 A1
(43) Pub. Date: Dec. 18, 2025

(54) Server Information Handling System with Configurable Power Supply Unit Bay System

(71) Applicant: Dell Products L.P., Round Rock, TX (US)

(72) Inventors: Haocheng Ku, Taipei City (TW); Yufeng Lin, Taipei City (TW); Yi-Chang Chen, New Taipei City (TW); Eduardo Escamilla, Round Rock, TX (US); Yuehchun Tsai, Taoyuan City (TW)

(21) Appl. No.: 18/745,751

(22) Filed: Jun. 17, 2024

(51) Int. Cl. H05K 7/14

(52) U.S. Cl. CPC H05K 7/1492

(57) ABSTRACT

A configurable power supply bay system. The configurable power supply bay system includes a power supply bay and a power supply bay system configuration component, the power supply bay configuration component being configured to be mounted to the power supply bay, the power supply configuration component configuring the power supply bay to mount a plurality of types of power supply units within the power supply bay, each of the plurality of types of power supply units having respective external characteristics.

### BACKGROUND OF THE INVENTION

### Field of the Invention

The present invention relates to information handling systems. More specifically, embodiments of the invention relate to server type information handling systems within information technology (IT) environments.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

It is known to use information handling systems and related IT systems within information technology (IT) environments such as data centers.

### SUMMARY OF THE INVENTION

A system and method for providing a configurable power supply unit bay system.

In one embodiment, the invention relates to an apparatus for configurating a power supply bay, the apparatus comprising: a power supply bay system configuration component, the power supply bay configuration component being configured to be mounted to a power supply bay, the power supply configuration component configuring the power supply bay to mount a plurality of types of power supply units within the power supply bay, each of the plurality of types of power supply units having respective external characteristics.

In another embodiment, the invention relates to a configurable power supply bay system comprising: a power supply bay; and, a power supply bay system configuration component, the power supply bay configuration component being configured to be mounted to the power supply bay, the power supply configuration component configuring the power supply bay to mount a plurality of types of power supply units within the power supply bay, each of the plurality of types of power supply units having respective external characteristics.

In another embodiment, the invention relates to a system comprising: a processor; a data bus coupled to the processor; a power supply; and, a configurable power supply bay system mounting the drive, the configurable power supply bay system comprising: a power supply bay; and, a power supply bay system configuration component, the power supply bay configuration component being configured to be mounted to the power supply bay, the power supply configuration component configuring the power supply bay to mount a plurality of types of power supply units within the power supply bay, each of the plurality of types of power supply units having respective external characteristics.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 shows a general illustration of components of an information handling system as implemented in the system and method of the present invention.

FIG. 2 shows a perspective view of a portion of a data center within an IT environment.

FIG. 3 shows a generalized perspective view of an example rack server type information handling system.

FIGS. 4A and 4B, generally referred to as FIG. 4, respectively show perspective and top views of a first type of power supply.

FIGS. 5A and 5B, generally referred to as FIG. 5, respectively show perspective and top views of a second type of power supply.

FIGS. 6A and 6B, generally referred to as FIG. 6, respectively show perspective and front views of a first type of power supply mounted within a configurable power supply bay system.

FIG. 7 shows a perspective view of power supply bay spacers used with a configurable power supply bay system.

FIGS. 8A and 8B, generally referred to as FIG. 8, respectively show left and right perspective views of a configurable power supply bay system with power supply bay spacer and alignment components installed.

FIG. 9 shows a detailed view of the interaction of a power supply bay attachment component and a side wall of a configurable power supply bay system.

FIGS. 10A and 10B, generally referred to as FIG. 10, respectively show perspective views of a configurable power supply bay system without a bay guard bracket component installed and with a bay guard bracket installed.

FIG. 11 shows a perspective view of a bay guard bracket component used with a configurable power supply bay system.

FIGS. 12A and 12B, generally referred to as FIG. 12, respectively show a rear perspective view of a configurable power supply bay system with an installed first type of power supply and an installed second type of power supply.

### DETAILED DESCRIPTION

Various aspects of the disclosure include an appreciation that server type information handling systems can be configured with a plurality of types of power supplies. Various aspects of the present disclosure include an appreciation that the plurality of types of power supplies can conform to a power supply standard such as a Modular Hardware System-Common Redundant Power Supply (M-CRPC) standard.

Various aspects of the present disclosure include an appreciation that the plurality of types of power supplies can have different external characteristics. Various aspects of the present disclosure include an appreciation that the different external characteristics can include dimension characteristics, mounting alignment characteristics, external physical characteristics, or a combination thereof. For example, certain known types of power supplies can have a width of substantially 60 mm while other types of power supplies can have a width of substantially 73.5 mm. Various aspects of the present disclosure include an appreciation that the types of power supplies having a particular width might also have respective mounting alignment characteristics, respective external housing characteristics, or a combination thereof.

Various aspects of the present disclosure include an appreciation that a customer may wish to replace one type of power supply with another type of power supply in the field. Various aspects of the disclosure include an appreciation that server type information handling systems it would be desirable to provide power supply bays which could be configured for receiving a plurality of types of power supplies.

A system and method are disclosed for providing a power supply system with a configurable power supply unit bay system. In certain embodiments, the power supply system includes a power supply unit and a configurable power supply unit bay system. In certain embodiments, the configurable power supply unit bay system can be configured to function with a plurality of types of power supplies. In certain embodiments, the plurality of types of power supplies includes respective external characteristics. In certain embodiments, the external characteristics include dimension characteristics, mounting alignment characteristics, external physical characteristics, or a combination thereof.

In certain embodiments, the configurable power supply unit bay system includes a bay housing, one or more bay system configuration components, or a combination thereof. In certain embodiments, the one or more configuration components include a first power supply bay spacer and alignment component, a second power supply bay spacer and alignment component, or a combination thereof. In certain embodiments, the one or more bay system configuration components of the configurable power supply unit bay system further includes a bay guard bracket component. Such a configurable power supply unit bay solution advantageously allows a single power supply bay to function with a plurality of types of power supply units.

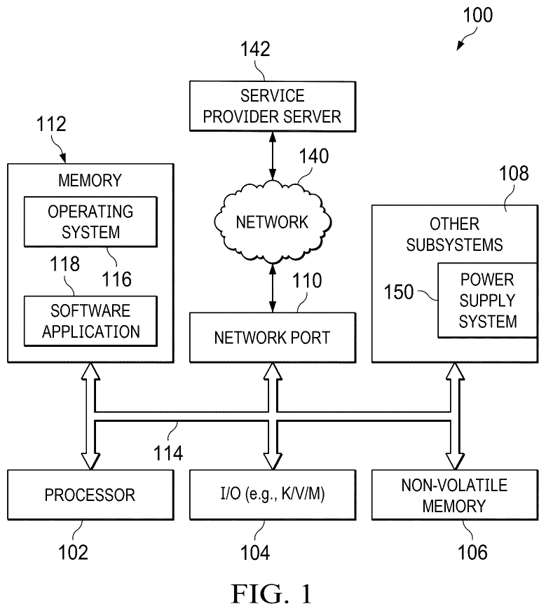

FIG. 1 shows a generalized illustration of an information handling system 100 that can be used to implement the system and method of the present invention. The information handling system 100 includes a processor (e.g., central processor unit or “CPU”) 102, input/output (I/O) devices 104, such as a display, a keyboard, a mouse, and associated controllers, a hard drive or disk storage 106, and various other subsystems 108. In various embodiments, the information handling system 100 also includes network port 110 operable to connect to a network 140, which is likewise accessible by a service provider server 142. The information handling system 100 likewise includes system memory 112, which is interconnected to the foregoing via one or more buses 114. System memory 112 further comprises operating system (OS) 116. In certain embodiments, the information handling system 100 is one of a plurality of information handling systems within a data center. In certain embodiments, the information handling system 100 comprises a server type information handling system. In certain embodiments, the server type information handling system is configured to be mounted within a server rack. In certain embodiments, the other subsystem 108 includes one or more power system 150 for supplying power to the other components of the information handling system 100.

In certain embodiments, the information handling system 100 comprises a server type information handling system. In certain embodiments, the server type information handling system comprises a rack server type information handling system. As used herein, a rack server type information handling system broadly refers to an information handling system which is physically configured to be mounted within a server rack.

In certain embodiments, each power supply system 150 includes a respective power supply unit and a respective configurable power supply unit bay system. In certain embodiments, the configurable power supply unit bay system can be configured to function with a plurality of types of power supplies. In certain embodiments, the plurality of types of power supplies includes respective external characteristics. In certain embodiments, the external characteristics include dimension characteristics, mounting alignment characteristics, external physical characteristics, or a combination thereof.

In certain embodiments, the configurable power supply unit bay system includes a bay housing, one or more bay system configuration components, or a combination thereof. In certain embodiments, the one or more configuration components include a first power supply bay spacer and alignment component, a second power supply bay spacer and alignment component, or a combination thereof. In certain embodiments, the one or more bay system configuration components of the configurable power supply unit bay system further includes a bay guard bracket component. Such a configurable power supply unit bay solution advantageously allows a single power supply bay to function with a plurality of types of power supply units.

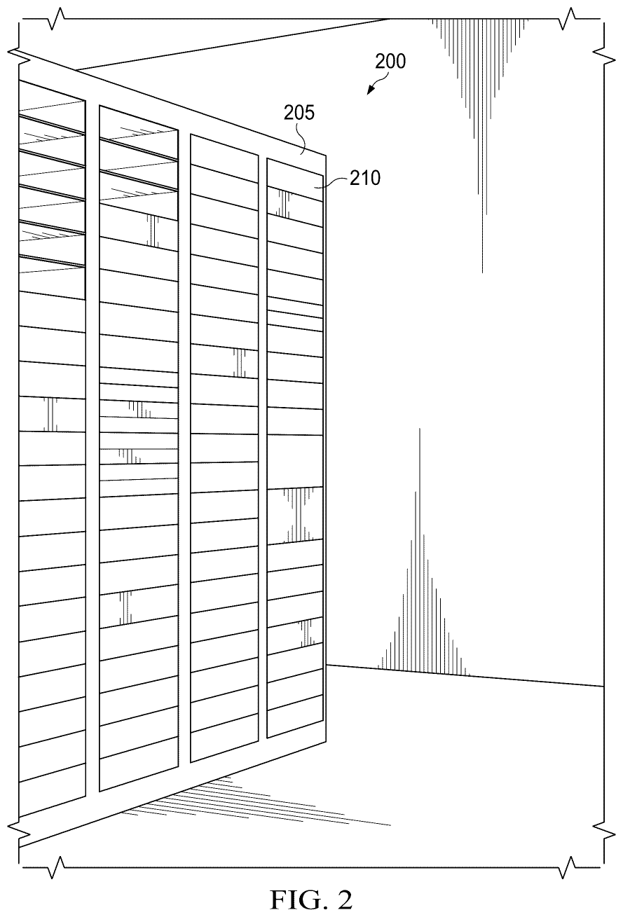

FIG. 2 shows a perspective view of a portion of an IT environment 200. The IT environment includes one or more racks 205 which include a plurality of information handling systems 100, often referred to as a server rack. In various embodiments, the IT environment 200 comprises a data center. As used herein, a data center refers to an IT environment which includes a plurality of networked information handling systems 100. In various embodiments, the information handling systems 100 of the data center include some or all of router type information handling systems, switch type information handling systems, firewall type information handling systems, storage system type information handling systems, server type information handling systems and application delivery controller type information handling systems. In certain environments, the information handling systems 100 are mounted within respective racks. As used herein, a rack refers to a physical structure that is designed to house the information handling systems 100 as well as the associated cabling and power provision for the information handling systems. In certain embodiments, a rack includes side panels to which the information handling systems are mounted. In certain embodiments, the rack includes a top panel and a bottom panel to which the side panels are attached. In certain embodiments, the side panels each include a front side panel and a rear side panel.

In certain embodiments, a plurality of racks is arranged continuous with each other to provide a rack system. An IT environment can include a plurality of rack systems arranged in rows with aisles via which IT service personnel can access information handling systems mounted in the racks. In certain embodiments, the aisles can include front aisles via which the front of the information handling systems may be accessed and hot aisles via which the infrastructure (e.g., data and power cabling) of the IT environment can be accessed.

Each respective rack includes a plurality of vertically arranged information handling systems 210. In certain embodiments, the information handling systems may conform to one of a plurality of standard server sizes. In certain embodiments, the plurality of server sizes conforms to particular rack unit sizes (i.e., rack units). As used herein, a rack unit broadly refers to a standardized server system height. As is known in the art, a server system height often conforms to one of a 1 U rack unit, a 2 U rack unit and a 4 U rack unit. In general, a 1 U rack unit is substantially (i.e., +/−20%) 1.75″ high, a 2 U rack unit is substantially (i.e., +/−20%) 3.5″ high and a 4 U rack height is substantially (i.e., +/−20%) 7.0″ high.

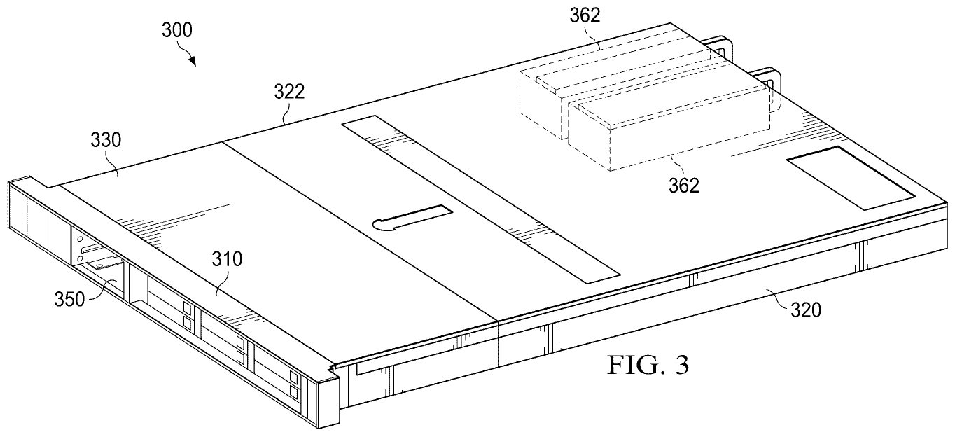

FIG. 3 shows a generalized perspective view of an example rack server type information handling system 300. In certain embodiments, the rack server type information handling system includes a front portion 310, which is accessible when the rack server type information handing system 300 is mounted on a server rack. In certain embodiments, the side portions 320, 322 mount to the rack via respective server mounting components. In certain embodiments, the side portions mount to the rack via respective mechanical guiding features which are mechanically coupled to respective server mounting components. In certain embodiments, the rack server type information handling system can slide out from the rack via the respective mechanical guiding features. In certain embodiments, internal components of the rack type information handling system 300 may be accessed by removing a top panel 330 of the rack type information handing system 300. In certain embodiments, the rack type information handing system 300 includes a bay 350 via which components may be mounted to the rack type information handling system.

In certain embodiments, the information handling system 300 includes one or more power supplies 360 mounted within respective power supply bay systems 362. In certain embodiments, each power supply 360 has a corresponding power supply type. In certain embodiments, the power supply types include power supplies which conform to a power supply standard such as a Modular Hardware System-Common Redundant Power Supply (M-CRPC) standard.

In various embodiments, the plurality of types of power supplies has different external characteristics. In various embodiments, the different external characteristics include dimension characteristics, mounting alignment characteristics, external physical characteristics, or a combination thereof. For example, in certain embodiments, a power supply conforming to a first type of power supply has a width of substantially (i.e., +/−20%) 60 mm while other types of power supplies can have a width of substantially (i.e., +/−20%) 73.5 mm. In certain embodiments, the types of power supplies having particular widths also have respective mounting alignment characteristics, respective external housing characteristics, or a combination thereof.

In certain embodiments, one or more of the power supply bay systems 362 include a respective configurable power supply unit bay system. In certain embodiments, the configurable power supply unit bay system can be configured to function with a plurality of types of power supplies. In certain embodiments, the plurality of types of power supplies includes respective external characteristics. In certain embodiments, the external characteristics include dimension characteristics, mounting alignment characteristics, external physical characteristics, or a combination thereof.

In certain embodiments, the configurable power supply unit bay system includes a bay housing, one or more bay system configuration components, or a combination thereof. In certain embodiments, the one or more configuration components include a first power supply bay spacer and alignment component, a second power supply bay spacer and alignment component, or a combination thereof. In certain embodiments, the one or more bay system configuration components of the configurable power supply unit bay system further includes a bay guard bracket component. Such a configurable power supply unit bay solution advantageously allows a single power supply bay to function with a plurality of types of power supply units.

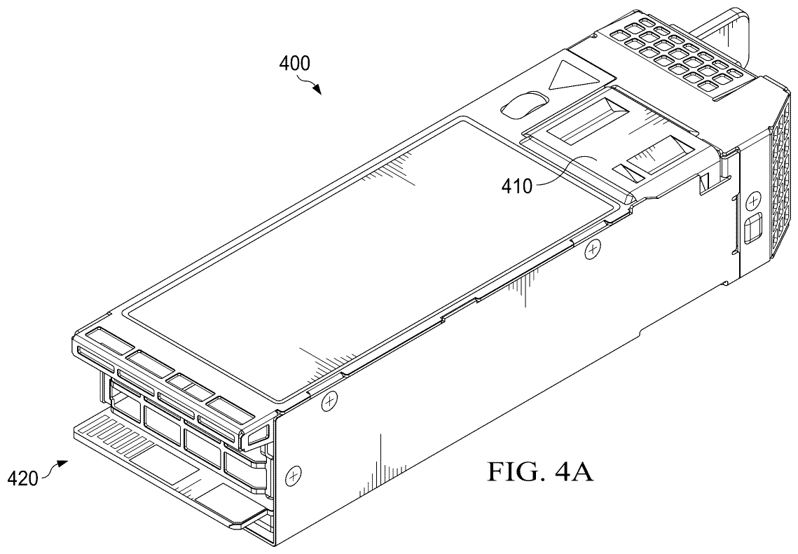

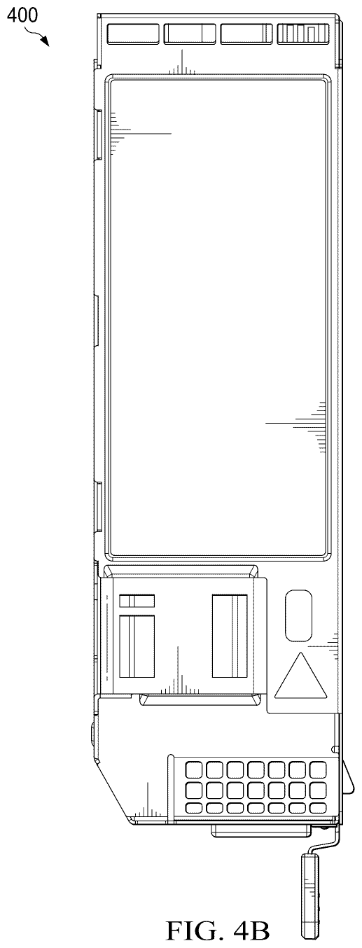

FIGS. 4A and 4B, generally referred to as FIG. 4, show various views of a first type of power supply. More specifically, FIG. 4a shows a perspective view of a first type of power supply and FIG. 4B shows a top view of the first type of power supply 400.

In certain embodiments, the first type of power supply has a width of substantially (i.e., +/−20%) 60 mm. In certain embodiments, the first type of power supply also has respective mounting alignment characteristics, respective external housing characteristics, or a combination thereof. For example, the alignment characteristics and external housing characteristics may include a particular top housing configuration 410. Also for example, the external housing characteristics may include a particular rear housing configuration 420.

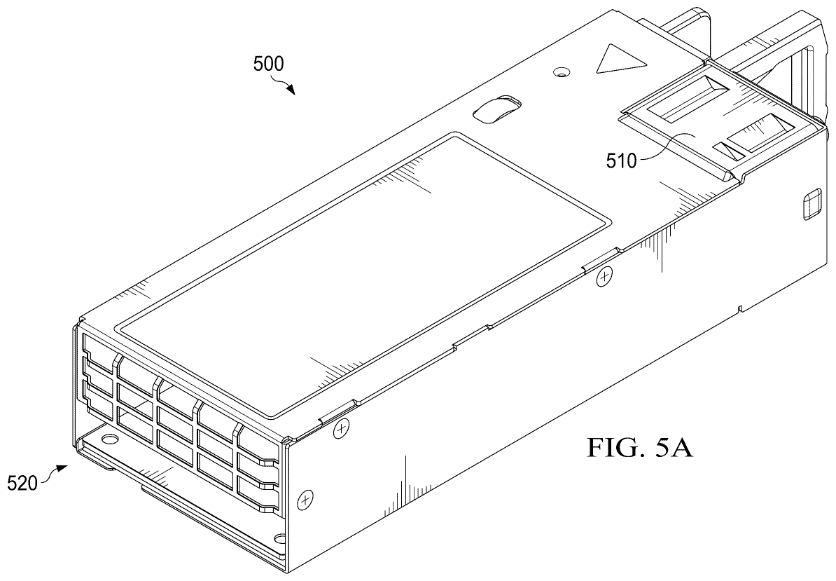

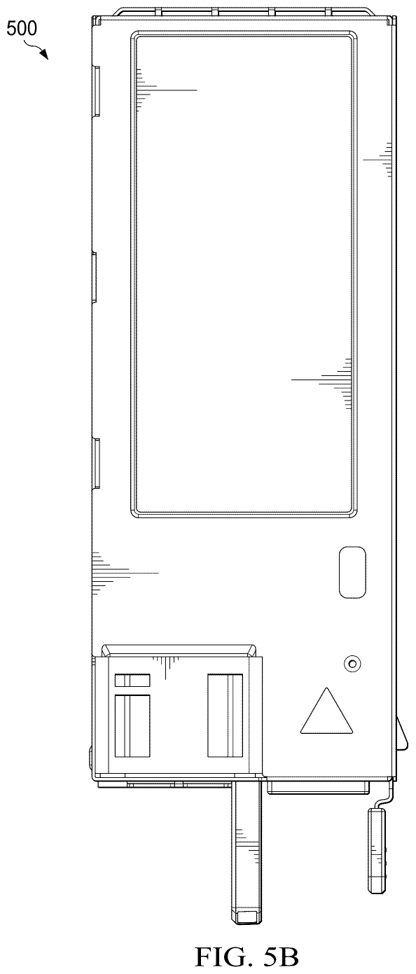

FIGS. 5A and 5B, generally referred to as FIG. 5, show various views of a second type of power supply 500. More specifically, FIG. 5A shows a perspective view of a second type of power supply 500 and FIG. 5B shows a top view of the second type of power supply 400.

In certain embodiments, the second type of power supply has a width of substantially (i.e., +/−20%) 73.5 mm. In certain embodiments, the second type of power supply also has respective mounting alignment characteristics, respective external housing characteristics, or a combination thereof. For example, the alignment characteristics and external housing characteristics may include a particular top housing configuration 510. Also for example, the external housing characteristics may include a particular rear housing configuration 520.

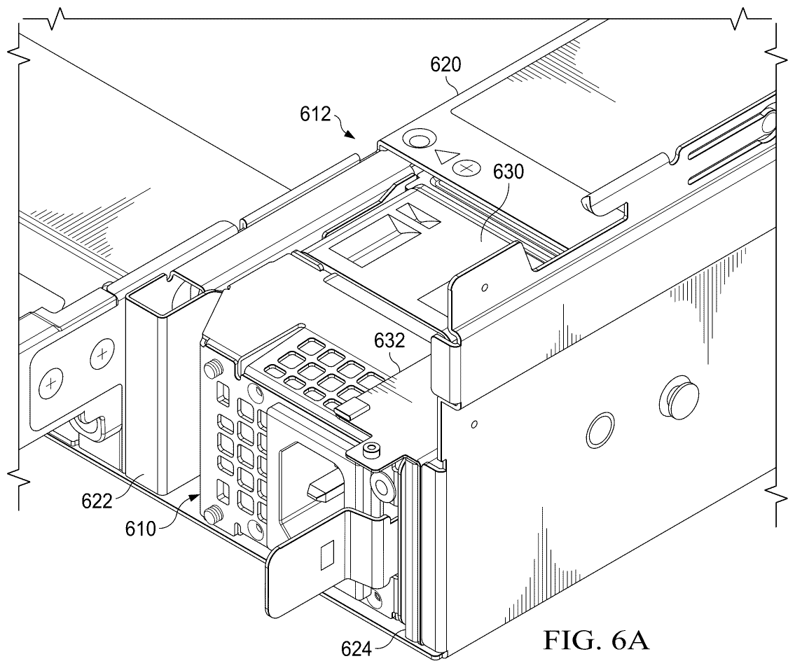

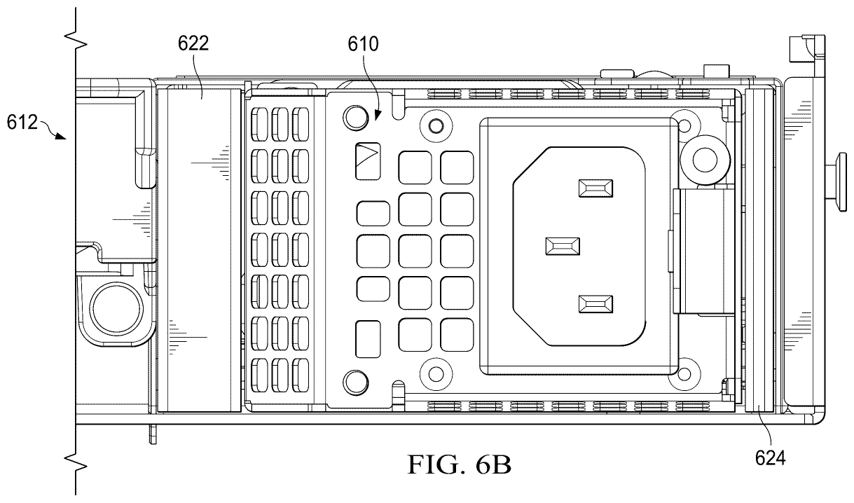

FIGS. 6A and 6B, generally referred to as FIG. 6, show various views of a first type of power supply 610 mounted within a configurable power supply bay system 612. More specifically, FIG. 6A shows a perspective view of a first type of power supply 610 mounted within a configurable power supply bay system 612 and FIG. 6B front views of a first type of power supply 610 mounted within a configurable power supply bay system 612.

In certain embodiments, the configurable power supply bay system 612 includes a bay housing 620, a first power supply bay spacer and alignment component 622, a second power supply bay spacer 624 and alignment component, or a combination thereof. In certain embodiments, the first power supply bay spacer and alignment component 622 has a corresponding first width. In certain embodiments, the second power supply bay spacer and alignment component 624 has a corresponding second width. In certain embodiments, the first width is greater than the second width. In certain embodiments, the first width of the first power supply bay spacer and alignment component 622 being greater than the second width of the second power supply bay spacer and alignment component 624 aligns the power supply 610 when the power supply is mounted within the configurable power supply bay system 612. In certain embodiments, the first width of the first power supply bay spacer and alignment component 622 being greater than the second width of the second power supply bay spacer and alignment component 624 laterally offsets the power supply 610 when the power supply is mounted within the configurable power supply bay system 612.

In certain embodiments, the first power supply bay spacer and alignment component 622 and a second power supply bay spacer 624 guide the power supply unit 610 into a wider power supply bay housing 620. In certain embodiments, the first power supply bay spacer and alignment component 622 and a second power supply bay spacer 624 ensures accurate power supply unit connector mating when the power supply unit is mounted in the configurable power supply unit bay system 612. In certain embodiments, the first power supply bay spacer and alignment component 622 and a second power supply bay spacer 624 prevent incorrect power supply unit 610 positioning when mounted in the configurable power supply unit bay system 612.

In certain embodiments, the first power supply bay spacer and alignment component 622 and a second power supply bay spacer 624 aligns a top wall 630 of the power supply 610 with an alignment portion 632 of the bay housing 620 when the power supply 610 is mounted within the configurable power supply bay system 612. In certain embodiments, the top wall 630 of the power supply 620 includes an alignment portion which aligns with the alignment portion 632 of the bay housing 620. In certain embodiments, the first power supply bay spacer and alignment component 622 causes the alignment portion of the top wall 630 of the power supply 610 to be laterally offset from an outer wall of the bay housing 620.

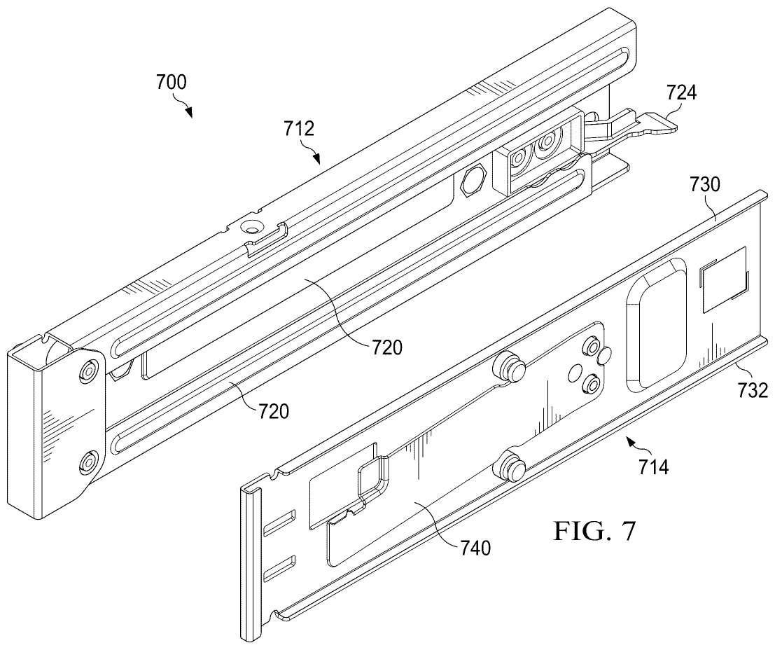

FIG. 7 shows a perspective view of a power supply bay spacer and alignment system 700 used with a configurable power supply bay system.

In certain embodiments, the power supply bay spacer and alignment system 700 includes a first power supply bay spacer and alignment component 712, a second power supply bay spacer and alignment component 714, or a combination thereof. In certain embodiments, the first power supply bay spacer and alignment component 712 has a corresponding first width. In certain embodiments, the second power supply bay spacer and alignment component 714 has a corresponding second width. In certain embodiments, the first width is greater than the second width. In certain embodiments, the first width of the first power supply bay spacer and alignment component 712 being greater than the second width of the second power supply bay spacer and alignment component 714 aligns a power supply when the power supply is mounted within the configurable power supply bay system. In certain embodiments, the first width of the first power supply bay spacer and alignment component 712 being greater than the second width of the second power supply bay spacer and alignment component 714 laterally offsets the power supply when the power supply is mounted within the configurable power supply bay system.

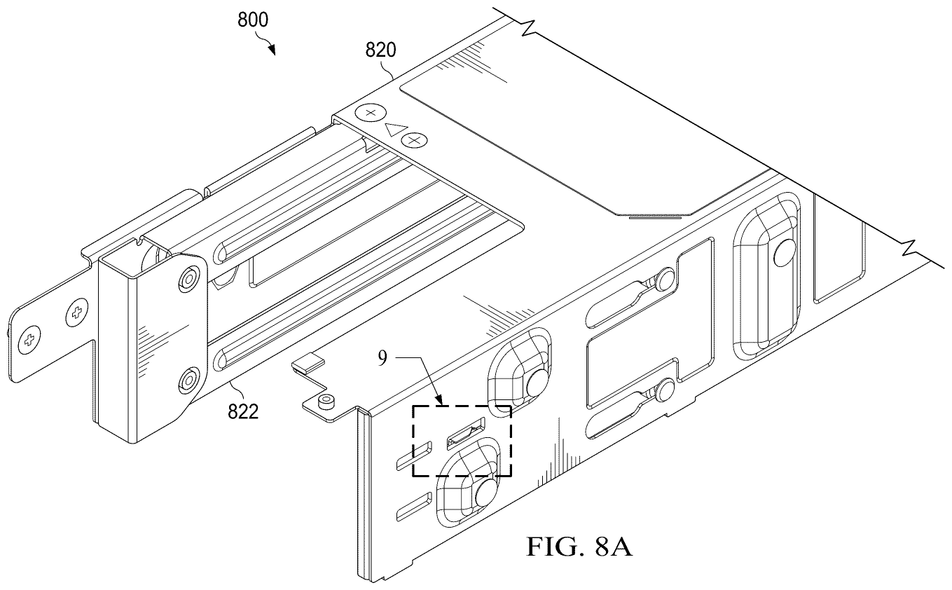

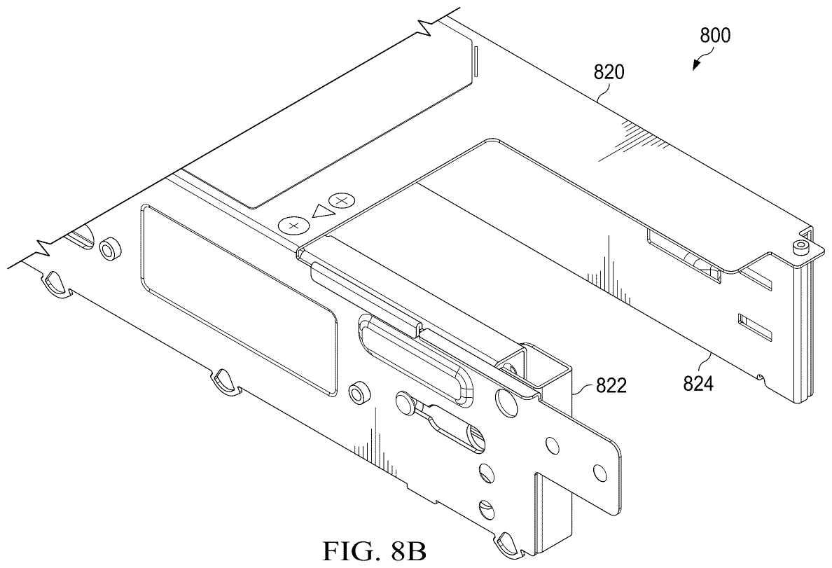

In certain embodiments, the first power supply bay spacer and alignment component 712 includes horizontal ribs 720 which assist in mounting a power supply within the configurable power supply bay system. In certain embodiments, a top wall 722 of the first power supply bay spacer and alignment component 712 defines an aperture via which a fastener may be used to physically attach the first power supply bay spacer and alignment component 712 to a top wall of the bay housing. In certain embodiments, an outside wall of the first power supply bay spacer and alignment component 712 includes a projection (see e.g., FIG. 8B) via which the first power supply bay spacer and alignment component 712 may be physically attached to a side wall of the bay housing. In certain embodiments, the first power supply bay spacer and alignment component 712 includes a connector projection 724 which mates with a portion of the system power supply connector to assure that when a first type of power supply is mounted within the configurable power supply bay system, the power supply is connected to the proper portion of the system power supply connector.

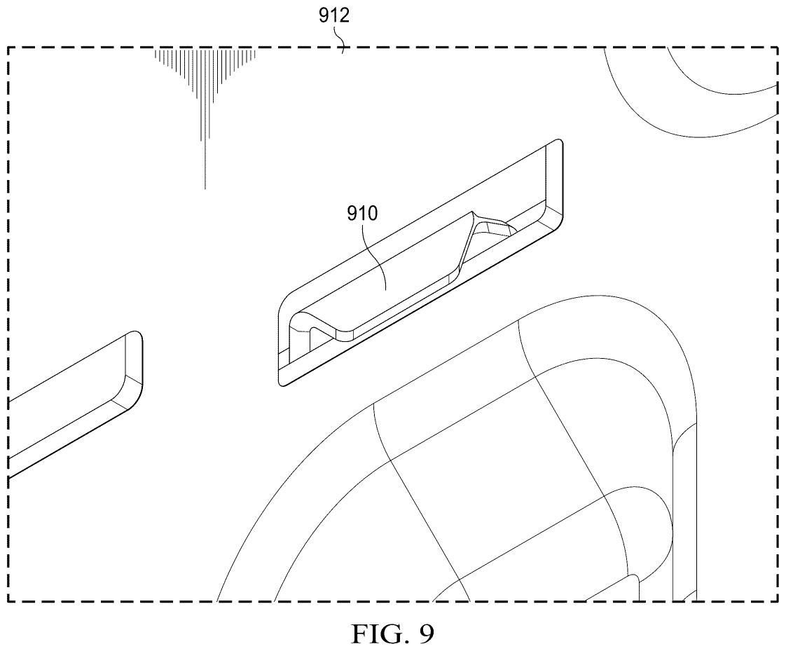

In certain embodiments, the second power supply bay spacer and alignment component 714 include a top edge 730, a bottom edge 732, or a combination thereof. In certain embodiments, the top edge 730, the bottom edge 732, or the combination thereof, offset an inside wall of the second power supply bay spacer and alignment component 714 from an inside wall of a bay housing. In certain embodiments, an outside wall of the second power supply bay spacer and alignment component 714 includes a mounting device 740 which includes an edge projection 742 via which the second power supply bay spacer and alignment component 712 may be physically attached to a side wall of the bay housing (see e.g., FIG. 9).

FIGS. 8A and 8B, generally referred to as FIG. 8, show views of a configurable power supply bay system 800 with power supply bay spacer and alignment components installed. More specifically, FIG. 8A show a left perspective view of a configurable power supply bay system 800 with power supply bay spacer and alignment components installed and FIG. 8B show a right perspective view of a configurable power supply bay system 800 with power supply bay spacer and alignment components installed.

In certain embodiments, the configurable power supply bay system 812 includes a bay housing 820, a first power supply bay spacer and alignment component 822, a second power supply bay spacer 824 and alignment component, or a combination thereof. In certain embodiments, the first power supply bay spacer and alignment component 822 has a corresponding first width. In certain embodiments, the second power supply bay spacer and alignment component 824 has a corresponding second width. In certain embodiments, the first width is greater than the second width. In certain embodiments, the first width of the first power supply bay spacer and alignment component 822 being greater than the second width of the second power supply bay spacer and alignment component 824 aligns a power supply when the power supply is mounted within the configurable power supply bay system 800. In certain embodiments, the first width of the first power supply bay spacer and alignment component 822 being greater than the second width of the second power supply bay spacer and alignment component 824 laterally offsets the power supply when the power supply is mounted within the configurable power supply bay system.

In certain embodiments, the first power supply bay spacer and alignment component 822 and a second power supply bay spacer 824 aligns a top wall of a power supply with an alignment portion 832 of the bay housing 820 when the power supply is mounted within the configurable power supply bay system 800. In certain embodiments, the top wall of the power supply includes an alignment portion which aligns with the alignment portion 832 of the bay housing. In certain embodiments, the first power supply bay spacer and alignment component 822 causes the alignment portion of the top wall 830 of the power supply 810 to be laterally offset from an outer wall of the bay housing 820.

FIG. 9 shows a detailed view of the interaction of a power supply bay attachment component 910 and a side wall 912 of a device bay of a configurable power supply bay system. More specifically, the side wall 912 defines an aperture which mates with a projection 822 extending from the power supply bay attachment component 910. In certain embodiments, the projection 822 extends substantially perpendicular from a main wall of the power supply bay attachment component 810.

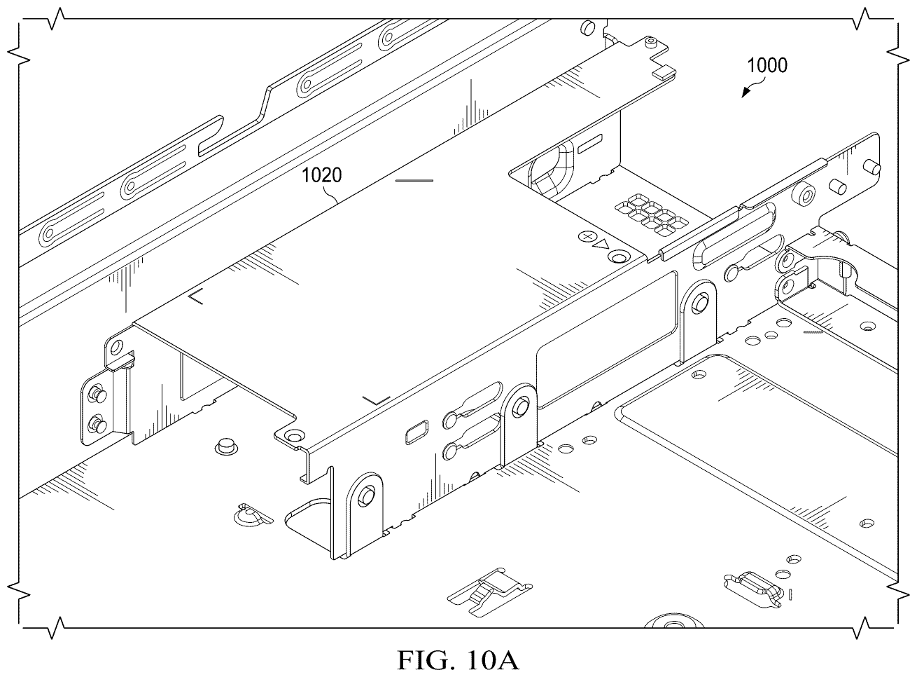

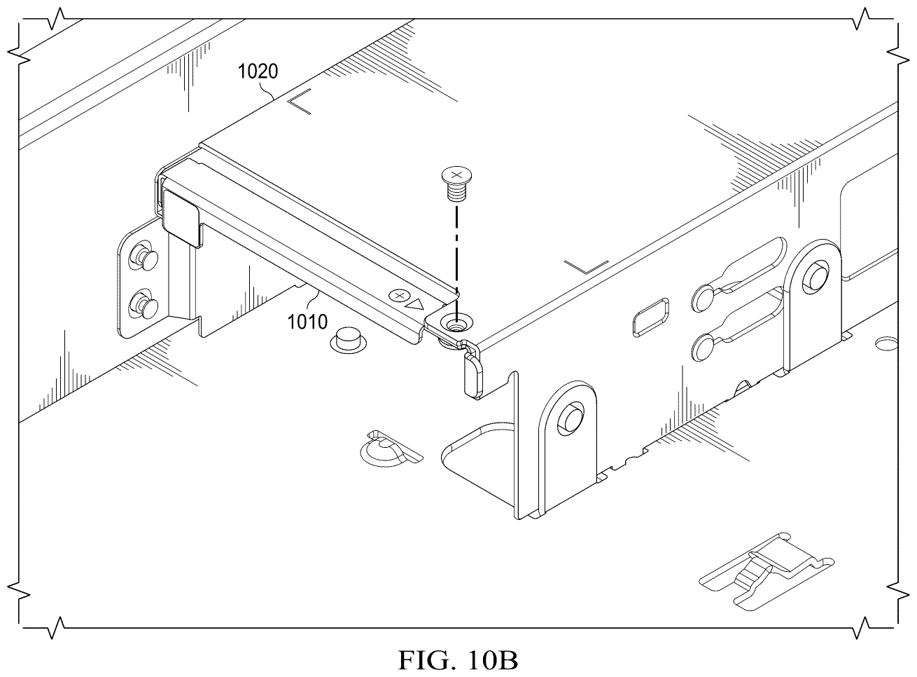

FIGS. 10A and 10B, generally referred to as FIG. 10, show views of a configurable power supply bay system 1000. More specifically, FIG. 10A shows a perspective view of a configurable power supply bay system 1000 without a bay guard bracket component installed and FIG. 10B shows a perspective view of a configurable power supply bay system 1000 with a bay guard bracket 1010 installed.

In certain embodiments, the configurable power supply bay system 1000 includes a rear bay feature which is used to prevent mounting of an incorrect power supply type (e.g., a power supply type of having incorrect external features such as an incorrect power form factor). More specifically, when the configurable power supply bay system is assembled with a bay guard bracket 1010 is installed at the rear of the power supply bay, a first type of power supply cannot be completely installed into the configurable power supply bay system 1000 whereas a second type of power supply can be installed into the configurable power supply bay system 1000.

In certain embodiments, a top wall of the rear of the power supply bay defines a recess into which the bay guard bracket 1010 fits. In certain embodiments, the top wall of the rear of the power supply bay defines an aperture through which a fastener may be inserted to fasten the bay guard bracket 1010 to the top wall of the rear of the power supply bay.

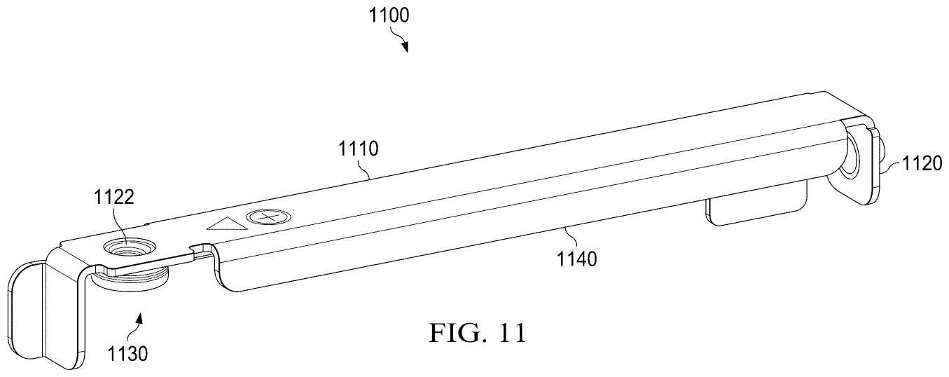

FIG. 11 shows a perspective view of a bay guard bracket component 1100 used with a configurable power supply bay system. In certain embodiments, the bay guard bracket 1100 includes a top wall portion 1110, a front side portion 1112, a back side portion 1114, a first side portion 1116, a second side portion 1118, or a combination thereof. In certain embodiments, the top wall portion 1110, the front side portion 1112, the back side portion 1114, the first side portion 1116, the second side portion 1118, or a combination thereof, are integrated in a single piece of material. In certain embodiments, the bay guard bracket 1110 further includes a fastener receptacle 1120 via which the bay guard bracket 1100 may be attached to a power supply bay.

In certain embodiments, the front side portion 1112 extends substantially (i.e., +/−20%) perpendicularly to the top wall portion 1110. In certain embodiments, the front side portion 1112 extends substantially (i.e., +/−20%) downwardly from the top wall portion 1110. In certain embodiments, the back side portion 1114 extends substantially (i.e., +/−20%) perpendicularly to the top wall portion 1110. In certain embodiments, the back side portion 1114 extends substantially (i.e., +/−20%) downwardly from the top wall portion 1110. In certain embodiments, the first side portion 1116 extends substantially (i.e., +/−20%) perpendicularly to the top wall portion 1110. In certain embodiments, the first side portion 1116 extends substantially (i.e., +/−20%) downwardly from the top wall portion 1110. In certain embodiments, the second side portion 1118 extends substantially (i.e., +/−20%) perpendicularly to the top wall portion 1110. In certain embodiments, the second side portion 1118 extends substantially (i.e., +/−20%) downwardly from the top wall portion 1110.

In certain embodiments, the back side portion 1114 defines one or more air flow apertures 1130. In certain embodiments, the first side portion 1116 includes a side wall 1140, a front wall projection 1142, or a combination thereof. In certain embodiments, the front wall projection 1142 extends substantially (i.e., +/−20%) perpendicularly to the side wall 1140. In certain embodiments, the front wall projection 1142 extends substantially (i.e., +/−20%) sidewardly from the side wall 1140. In certain embodiments, the second side portion 1118 includes a side wall 1150, a side wall projection 1152, or a combination thereof. In certain embodiments, the side wall projection 1152 extends substantially (i.e., +/−20%) perpendicularly to the side wall 1140. In certain embodiments, the side wall projection 1152 extends substantially (i.e., +/−20%) sidewardly from the side wall 1150.

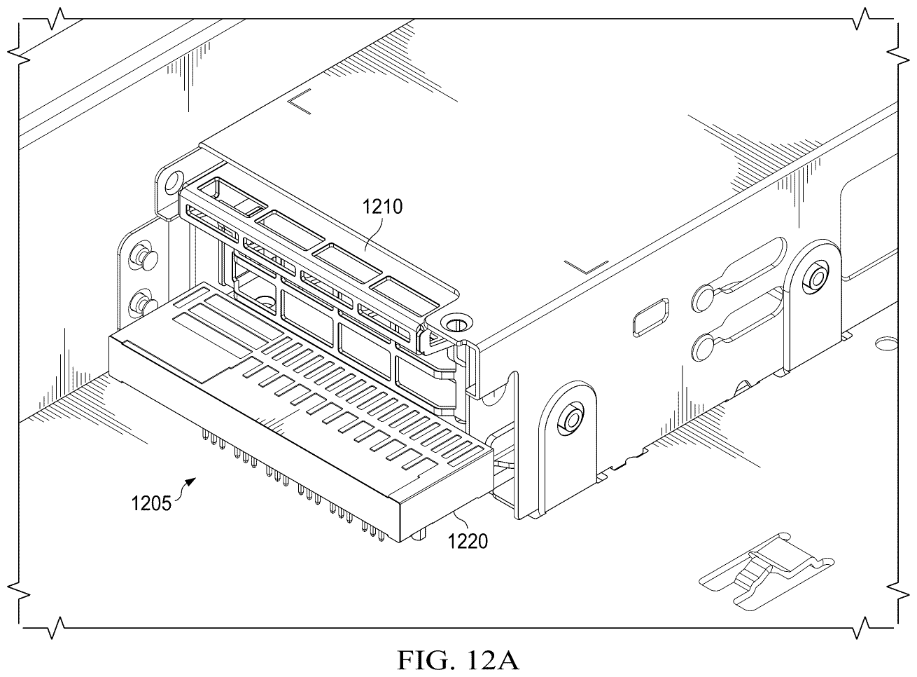

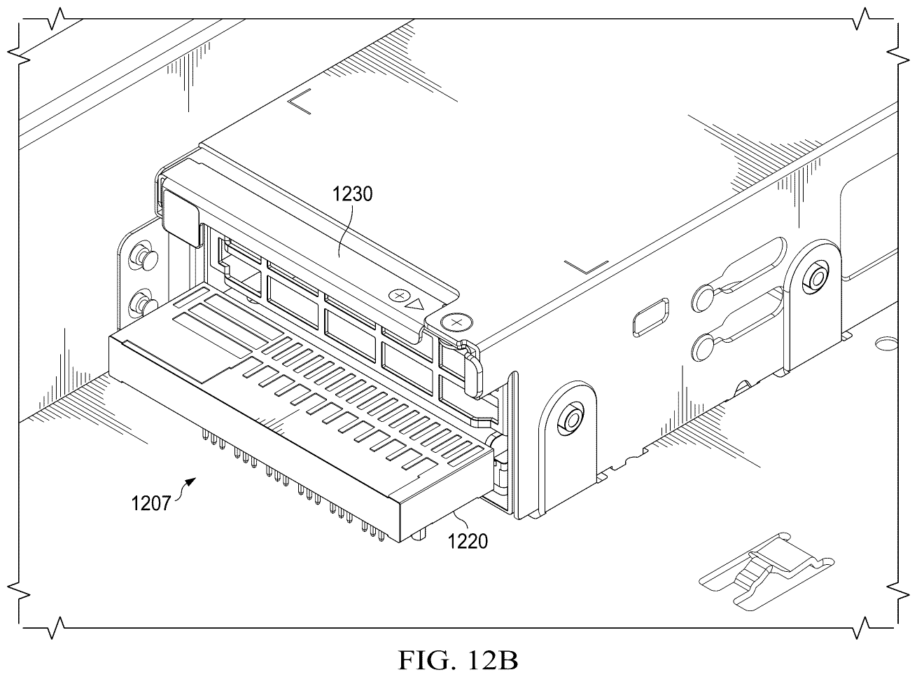

FIGS. 12A and 12B, generally referred to as FIG. 12, respectively show rear perspective views of a configurable power supply system. More specifically, FIG. 12A shows a rear perspective view of a configurable power supply bay system with an installed first type of power supply 1205 and FIG. 12B shows a rear perspective view of a configurable power supply system with an installed second type of power supply 1207.

In certain embodiments, the configurable power supply bay system 120 includes a rear bay feature which is used to prevent insertion of a power supply of incorrect power form factor. More specifically, when the configurable power supply bay system is assembled with a bay guard bracket 1210 is installed at the rear of the power supply bay, a first type of power supply cannot be completely installed into the configurable power supply bay system 1200 (i.e., cannot be coupled to a power supply connector 1220) whereas a second type of power supply can be installed into the configurable power supply bay system 1000.

Accordingly, the bay guard bracket component 1210 acts as protection to ensure customer cannot install a first type of power supply (e.g., a 60 mm wide power supply) without installing spacers and removing the guard bracket. In certain embodiments, the process of removing the guard bracket encourages a user to power off the server system when exchanging power supply types.

The present invention is well adapted to attain the advantages mentioned as well as others inherent therein. While the present invention has been depicted, described, and is defined by reference to particular embodiments of the invention, such references do not imply a limitation on the invention, and no such limitation is to be inferred. The invention is capable of considerable modification, alteration, and equivalents in form and function, as will occur to those ordinarily skilled in the pertinent arts. The depicted and described embodiments are examples only, and are not exhaustive of the scope of the invention.

Consequently, the invention is intended to be limited only by the spirit and scope of the appended claims, giving full cognizance to equivalents in all respects.

What is claimed is:

1. An apparatus for configurating a power supply bay, the apparatus comprising:
a power supply bay system configuration component, the power supply bay configuration component being configured to be mounted to a power supply bay, the power supply configuration component configuring the power supply bay to mount a plurality of types of power supply units within the power supply bay, each of the plurality of types of power supply units having respective external characteristics.

2. The apparatus of claim 1, wherein:
the power supply bay system configuration component comprises a power supply bay spacer and alignment component, the power supply bay spacer and alignment component being configured to be mounted to a side wall of the power supply bay.

3. The apparatus of claim 2, wherein:
the power supply bay system configuration component comprises another power supply bay spacer and alignment component, the another power supply bay spacer and alignment component being configured to be mounted to another side wall of the power supply bay, the another side wall of the power supply bay being positioned opposite to the side wall of the power supply bay.

4. The apparatus of claim 3, wherein:
the power supply bay spacer and alignment component has a corresponding power supply bay spacer and alignment component width;
the another power supply bay spacer and alignment component has a corresponding another power supply bay spacer and alignment component width; and
the corresponding power supply bay spacer and alignment component width and the corresponding another power supply bay spacer and alignment component width have different dimensions.

5. The apparatus of claim 1, wherein:
the power supply bay system configuration component comprises a bay guard bracket component, the bay guard bracket component preventing mounting of an incorrect power supply type.

6. The apparatus of claim 5, wherein:
the bay guard bracket is configured to be attached to a rear of the power supply bay.

7. A configurable power supply bay system comprising:
a power supply bay; and,
a power supply bay system configuration component, the power supply bay configuration component being configured to be mounted to the power supply bay, the power supply configuration component configuring the power supply bay to mount a plurality of types of power supply units within the power supply bay, each of the plurality of types of power supply units having respective external characteristics.

8. The drive mounting system of claim 7, wherein:
the power supply bay system configuration component comprises a power supply bay spacer and alignment component, the power supply bay spacer and alignment component being configured to be mounted to a side wall of the power supply bay.

9. The drive mounting system of claim 8, wherein:
the power supply bay system configuration component comprises another power supply bay spacer and alignment component, the another power supply bay spacer and alignment component being configured to be mounted to another side wall of the power supply bay, the another side wall of the power supply bay being positioned opposite to the side wall of the power supply bay.

10. The drive mounting system of claim 9, wherein:
the power supply bay spacer and alignment component has a corresponding power supply bay spacer and alignment component width;
the another power supply bay spacer and alignment component has a corresponding another power supply bay spacer and alignment component width; and
the corresponding power supply bay spacer and alignment component width and the corresponding another power supply bay spacer and alignment component width have different dimensions.

11. The drive mounting system of claim 7, wherein:
the power supply bay system configuration component comprises a bay guard bracket component, the bay guard bracket component preventing mounting of an incorrect power supply type.

12. The drive mounting system of claim 11, wherein:
the bay guard bracket is configured to be attached to a rear of the power supply bay.

13. A system comprising:
a processor;
a data bus coupled to the processor;
a power supply; and,
a configurable power supply bay system mounting the drive, the configurable power supply bay system comprising:
a power supply bay; and,
a power supply bay system configuration component, the power supply bay configuration component being configured to be mounted to the power supply bay, the power supply configuration component configuring the power supply bay to mount a plurality of types of power supply units within the power supply bay, each of the plurality of types of power supply units having respective external characteristics.

14. The system of claim 13, wherein:
the power supply bay system configuration component comprises a power supply bay spacer and alignment component, the power supply bay spacer and alignment component being configured to be mounted to a side wall of the power supply bay.

15. The system of claim 14, wherein:
the power supply bay system configuration component comprises another power supply bay spacer and alignment component, the another power supply bay spacer and alignment component being configured to be mounted to another side wall of the power supply bay, the another side wall of the power supply bay being positioned opposite to the side wall of the power supply bay.

16. The system of claim 15, wherein:
the power supply bay spacer and alignment component has a corresponding power supply bay spacer and alignment component width;
the another power supply bay spacer and alignment component has a corresponding another power supply bay spacer and alignment component width; and
the corresponding power supply bay spacer and alignment component width and the corresponding another power supply bay spacer and alignment component width have different dimensions.

17. The system of claim 13, wherein:
the power supply bay system configuration component comprises a bay guard bracket component, the bay guard bracket component preventing mounting of an incorrect power supply type.

18. The system of claim 17, wherein:
the bay guard bracket is configured to be attached to a rear of the power supply bay.
